(19) United States
(12) Patent Application Publication
(10) Pub. No.: US 2026/0206316 A1
(43) Pub. Date: Jul. 16, 2026

(54) THIN FILM TRANSISTOR PANEL, ITS CONTROL METHOD, AND MANUFACTURING METHOD

(71) Applicant: Xiamen Tianma Optoelectronics Co., Ltd., Xiamen (CN)

(72) Inventors: Guangya WU, Xiamen (CN); Xuhui PENG, Xiamen (CN); Jinquan LIU, Xiamen (CN); Zongcai DING, Xiamen (CN); Xiaohe LI, Xiamen (CN)

(21) Appl. No.: 19/074,882

(22) Filed: Mar. 10, 2025

(30) Foreign Application Priority Data
Jan. 13, 2025 (CN) 202510051504.4

(51) Int. Cl. H10D 86/40; G09G 3/00; H10D 86/01; H10D 86/60

(52) U.S. Cl. CPC H10D 86/441; G09G 3/006; H10D 86/021; H10D 86/60; G09G 2330/12

(57) ABSTRACT

A thin film transistor panel includes a substrate with a first surface and a transistor group arranged on the first surface. The first surface includes a pixel region that contains first transistors arranged in an array. In the same row of first transistors, the gates are connected to the same scan line, and the sources are connected to different signal lines. The transistor group includes transistor subgroups arranged sequentially. The transistor subgroups include second transistors. In the same transistor group, the gates, sources, and drains of the second transistors are connected to the same first trace, the same second trace, and the same third trace, respectively. The first and second transistors are arranged in the same layer. A side edge of the pixel region is parallel and opposite to the transistor group. The arrangement direction of the transistor subgroups is parallel to the length direction of the side edge.

### CROSS-REFERENCE TO RELATED APPLICATION

This application claims the priority of Chinese Patent Application No. 2025100515044, filed on Jan. 13, 2025, the content of which is incorporated herein by reference in its entirety.

### TECHNICAL FIELD

The present disclosure generally relates to the field of display technology and, more particularly, relates to thin film transistor panels, testing methods thereof, and manufacturing methods thereof.

### BACKGROUND

With the continuous development of science and technology, more and more electronic devices with display functions are widely used in people's daily life and work, bringing great convenience and becoming an indispensable and important tool for everyone today.

A display panel is the main component of an electronic device to realize display functions. Display panels use pixel circuits built with thin film transistors to control pixels for image display. In order to ensure the reliability of a display panel, it is necessary to conduct performance testing on transistors in a thin film transistor panel used to fabricate the display panel.

### SUMMARY

One aspect of the present disclosure provides a thin film transistor panel that includes a substrate having a first surface and at least one transistor group arranged on the first surface. The first surface includes at least one pixel region. The at least one pixel region includes first transistors arranged in an array. In the same row of the first transistors, gates of the first transistors are connected to the same scan line, and sources of the first transistors are connected to different signal lines. The at least one transistor group includes transistor subgroups arranged in sequence. The transistor subgroups include second transistors. In the same transistor group, gates of the second transistors are connected to the same first trace, sources of the second transistors are connected to the same second trace, and drains of the second transistors are connected to the same third trace. The first trace, second trace, and third trace are each connected to at least one solder pad. The second transistors and first transistors are arranged in the same layer. At least one side edge of the at least one pixel region is parallel and opposite to one of the at least one transistor group. The arrangement direction of the transistor subgroups in the at least one transistor group is parallel to the length direction of the at least one side edge that is parallel and opposite to the one of the at least one transistor group.

In another aspect of the present disclosure, a testing method for a thin film transistor panel is provided. The thin film transistor panel includes a substrate having a first surface and at least one transistor group arranged on the first surface. The first surface includes at least one pixel region. The at least one pixel region includes first transistors arranged in an array. In the same row of the first transistors, gates of the first transistors are connected to the same scan line, and sources of the first transistors are connected to different signal lines. The at least one transistor group includes transistor subgroups arranged in sequence. The transistor subgroups include second transistors. In the same transistor group, gates of the second transistors are connected to the same first trace, sources of the second transistors are connected to the same second trace, and drains of the second transistors are connected to the same third trace. The first trace, second trace, and third trace are each connected to at least one solder pad. The second transistors and first transistors are arranged in the same layer. At least one side edge of the at least one pixel region is parallel and opposite to one of the at least one transistor group. The arrangement direction of the transistor subgroups in the at least one transistor group is parallel to the length direction of the at least one side edge that is parallel and opposite to the one of the at least one transistor group. The method includes for the same transistor group of the at least one transistor group, applying a first test signal to a gate of the second transistors through a first solder pad connected to the first trace, providing a second test signal to a source of the second transistors through a second solder pad connected to the second trace, and obtaining a sampled signal through a third solder pad connected to the third trace; and determining whether there is a faulty first transistor in the at least one pixel region based on the sampled signal.

In another aspect of the present disclosure, a method for fabricating a thin film transistor panel includes providing a substrate with a first surface, wherein the first surface includes at least one pixel region; and forming first transistors and a transistor group on the substrate. The at least one pixel region includes the first transistors that are arranged in an array. In the same row of the first transistors, gates of the first transistors are connected to the same scan line, and sources of the first transistors are connected to different signal lines. The transistor group includes transistor subgroups arranged sequentially. One of the transistor subgroups includes a second transistor. In the same transistor group, gates of the second transistors are connected to the same first trace, sources of the second transistors are connected to the same second trace, and drains of the second transistors are connected to the same third trace. The first trace, the second trace, the third trace are each connected to at least one solder pad. The second transistor is arranged in the same layer as the first transistors. At least one side edge of the at least one pixel region is parallel and opposite to the transistor group. An arrangement direction of the transistor subgroups in the transistor group is parallel to the length direction of the at least one side edge of the at least one pixel region that is parallel and opposite to the transistor group.

Other aspects or embodiments of the present disclosure can be understood by those skilled in the art in light of the description, the claims, and the drawings of the present disclosure.

### BRIEF DESCRIPTION OF THE DRAWINGS

The accompanying drawings, which are incorporated in and constitute a part of the specification, illustrate embodiments of the present disclosure and, together with the description, serve to explain the principles of the present disclosure. The drawings are merely examples for illustrative purposes according to various disclosed embodiments and are not intended to limit the scope of the present disclosure.

The structures, proportions, sizes, etc. shown in the drawings of the present disclosure are only used to match the content disclosed in the present disclosure, for the understanding and reading of people familiar with the technology, not intended to limit the implementation of this application, and have no technical substantive significance. Without affecting the effectiveness and purpose of the present disclosure, any modification of structure, change of proportions, or adjustment of size should still fall within the scope of the technical content disclosed in the present disclosure.

FIG. 1 illustrates a top view of a thin film transistor panel.

FIG. 2 illustrates a structural diagram of an electrical test unit in the thin film transistor panel shown in FIG. 1.

FIG. 3 illustrates a top view of a thin film transistor panel according to various disclosed embodiments of the present disclosure.

FIG. 4a illustrates an equivalent circuit diagram of a transistor group opposite a first side according to various disclosed embodiments of the present disclosure

FIG. 4b illustrates an equivalent circuit diagram of a row of pixels in a pixel region and first transistors correspondingly connected to the pixels according to various disclosed embodiments of the present disclosure.

FIG. 5 illustrates a layout of a transistor group opposite a first side edge according to various disclosed embodiments of the present disclosure.

FIG. 6 illustrates a top view of another thin film transistor panel according to various disclosed embodiments of the present disclosure.

FIG. 7 illustrates a layout of a transistor group opposite a second side edge according to various disclosed embodiments of the present disclosure.

FIG. 8 illustrates an equivalent circuit diagram of a transistor group opposite a second side edge according to various disclosed embodiments of the present disclosure.

FIG. 9 illustrates a top view of yet another thin film transistor panel according to various disclosed embodiments of the present disclosure.

FIG. 10 illustrates a layout of a transistor group parallel and opposite to a pixel region in a column direction according to various disclosed embodiments of the present disclosure.

FIG. 11 illustrates a layout of a transistor group parallel and opposite to a pixel region in a row direction according to various disclosed embodiments of the present disclosure.

FIG. 12 illustrates a top view of yet another thin film transistor panel according to various disclosed embodiments of the present disclosure.

FIG. 13 illustrates a top view of a partial area of a thin film transistor panel according to various disclosed embodiments of the present disclosure.

FIG. 14 illustrates a top view of yet another thin film transistor panel according to various disclosed embodiments of the present disclosure.

FIG. 15 illustrates a cross-sectional view of a transistor group at a trace location according to various disclosed embodiments of the present disclosure.

FIG. 16 illustrates an equivalent circuit diagram of a transistor group according to various disclosed embodiments of the present disclosure.

FIG. 17 illustrates an equivalent circuit diagram of another transistor group according to various disclosed embodiments of the present disclosure.

FIG. 18 illustrates an equivalent circuit diagram of another transistor group according to various disclosed embodiments of the present disclosure.

FIG. 19 illustrates an equivalent circuit diagram of a thin film transistor panel according to various disclosed embodiments of the present disclosure.

FIG. 20 illustrates a top view of another thin film transistor panel according to various disclosed embodiments of the present disclosure.

FIG. 21 illustrates a top view of another thin film transistor panel according to various disclosed embodiments of the present disclosure.

FIG. 22 illustrates a top view of another thin film transistor panel according to various disclosed embodiments of the present disclosure.

FIG. 23 illustrates a top view of another thin film transistor panel according to various disclosed embodiments of the present disclosure.

FIG. 24 illustrates a top view of another thin film transistor panel according to various disclosed embodiments of the present disclosure.

FIG. 25 illustrates a top view of another thin film transistor panel according to various disclosed embodiments of the present disclosure.

FIG. 26 illustrates a top view of another thin film transistor panel according to various disclosed embodiments of the present disclosure.

FIG. 27 illustrates a flow chart of a testing method according to various disclosed embodiments of the present disclosure.

FIG. 28 illustrates a flow chart for determining a faulty first transistor based on a binary test method according to various disclosed embodiments of the present disclosure.

FIG. 29 illustrates a flow chart of a fabrication method for thin film transistor panels according to various disclosed embodiments of the present disclosure.

### DETAILED DESCRIPTION

Reference will now be made in detail to exemplary embodiments of the disclosure, which are illustrated in the accompanying drawings. Unless otherwise specifically stated, the relative arrangement of components and steps, numerical expressions, and numerical values set forth in these embodiments do not limit the scope of the invention.

The following description for at least one exemplary embodiment is merely illustrative in nature and in no way intended to limit the invention, its application, or uses.

Notably, similar reference numerals and letters indicate similar items in the following figures. Therefore, once an item is defined in one figure, it does not require further discussion in the following figures.

The present disclosure provides a thin film transistor panel, its testing method, and fabrication method. It achieves the purpose of performance testing on thin film transistors in the panel.

In a first aspect, a thin film transistor panel includes a substrate having a first surface and at least one transistor group disposed on the first surface. The first surface includes at least one pixel region, and the pixel region includes first transistors arranged in an array. In the same row of first transistors, gates of the first transistors are connected to the same scan line, and sources of the first transistors are connected to different signal lines. The transistor group includes transistor subgroups arranged in sequence. The transistor subgroups include second transistors. In the same transistor group, gates of the second transistors are connected to the same first trace, sources of the second transistors are connected to the same second trace, and drains of the second transistors are connected to the same third trace. The first trace, second trace, and third trace are each connected to at least one solder pad. The second transistors and first transistors are arranged in the same layer. At least one side edge of the pixel region is parallel and opposite to the transistor group. The arrangement direction of the transistor subgroups in the transistor group is parallel to the length direction of the at least one side edge that is parallel and opposite to the transistor group.

It may be seen from the above description that in the thin film transistor panel provided by the present disclosure, the first surface of the substrate has a pixel region and a transistor group. The pixel region is provided with first transistors arranged in an array, and the first transistors may be used to control pixels for image display. The transistor group includes transistor subgroups. The transistor subgroup includes second transistors that are in the same layer as the first transistors. Through the first trace, second trace, and third trace, the second transistors in the transistor group may be connected in parallel. Through solder pads connected with the first trace, second trace, and third trace, test signals may be applied to the transistor group and sampled signals may be obtained. Since the second transistors are arranged in the same layer as the first transistors, performance of the first transistors in the pixel region may be characterized based on sampled signals obtained by the second transistors. Performance test of the first transistors may be implemented to determine whether there is a faulty first transistor in the pixel region.

In a second aspect, a testing method for the above-illustrated thin film transistor panel is provided. The method includes:
For the same transistor group, applying first test signals to the gate of the second transistor through a solder pad connected with the first trace, providing second test signals to the source of the second transistor through a solder pad connected with the second trace, and obtaining sampled signals through a solder pad connected to the third signal; and
Determining whether there is a faulty first transistor in the pixel region based on the sampled signals.

Therefore, as illustrated above, test signals may be applied to the transistor group and sampled signals may be obtained through traces connected to the second transistors. Performance of the first transistors in the pixel region may be characterized through sampled signals obtained by the second transistors. Performance test of the first transistors may be implemented to determine whether there is a faulty first transistor in the pixel region.

In a third aspect, a manufacturing method of thin film transistor panel is provided. The method includes:
Providing a substrate having a first surface, wherein the first surface includes at least a pixel region; and
Forming first transistor and a transistor group on the substrate. The pixel region includes first transistors arranged in an array. In the same row of first transistors, gates of the first transistors are connected to the same scan line, and sources of the first transistors are connected to different signal lines. The transistor group includes transistor subgroups arranged in sequence. The transistor subgroup includes second transistors. In the same transistor group, gates of the second transistors are connected to the same first trace, sources of the second transistors are connected to the same second trace, and drains of the second transistors are connected to the same third trace. The first trace, the second trace, and the third trace are each connected to at least one solder pad. The second transistors are arranged in the same layer as the first transistors.

In this configuration, at least one side edge of the pixel region is parallel and opposite to the transistor group. The arrangement direction of the transistor subgroups in the transistor group is parallel to the length direction of the at least one edge that is parallel and opposite to the transistor group.

As described above, the preparation method provided in the present disclosure may be used to fabricate the aforementioned thin film transistor panel. It enables performance tests of the first transistors through the second transistors in the thin film transistor panel, thereby determining whether there is a faulty first transistor in the pixel region.

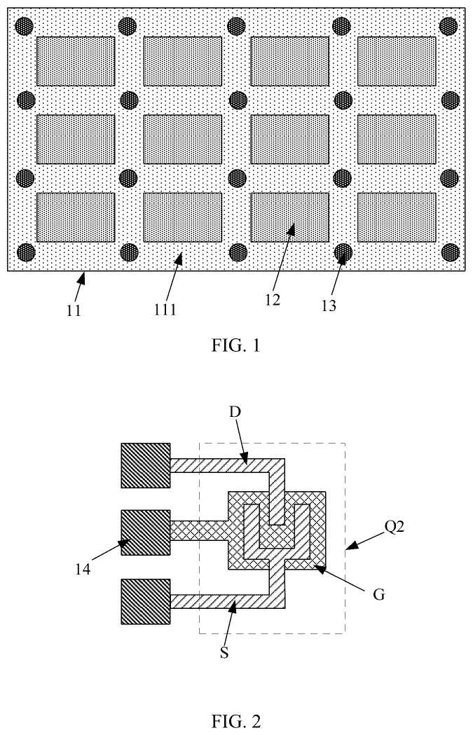

As described in the background section, to ensure the reliability of display panels, it is necessary to conduct performance tests on transistors in a thin film transistor panel used to make a display panel. As shown in FIG. 1, an electrical test unit, e.g., a test element group (TEG), may be configured in a thin film transistor panel to perform performance tests on transistors in the thin film transistor panel.

FIG. 1 illustrates a top view of a thin film transistor panel. FIG. 2 is a structural diagram of an electrical test unit in the thin film transistor panel shown in FIG. 1.

The thin film transistor panel includes a substrate 11 with a first surface 111 and electrical test units 13 over the first surface 111. The first surface 111 includes pixel regions 12 that each contain first transistors arranged in an array. The first transistors are used to connect pixels and control the pixels for image display. The first transistors are not shown in FIG. 1.

Electrical test units 13 are disposed on the first surface 111. Each of the four corners of every pixel region 12 is correspondingly provided with an electrical test unit 13, and adjacent corners of neighboring pixel regions 12 may share the same electrical test unit 13. The electrical test unit 13 includes a second transistor Q2. Each of a gate G, source S, and drain D of the second transistor Q2 is connected to a solder pad 14, respectively. The second transistor Q2 in the electrical test unit 13 is arranged in the same layer as the first transistors in the pixel region 12.

In the configurations shown in FIGS. 1 and 2, since the second transistors Q2 are uniformly distributed at selected points across the thin film transistor panel, the number of test points and corresponding second transistors Q2 are limited, resulting in a small testing range. The setup only allows for performance test of first transistors in a relatively small area directly opposite the pixel regions 12. As such, the test may not accurately reflect the performance of first transistors in the pixel region 12.

In view of this, an embodiment of the present disclosure provides a thin film transistor panel that includes a substrate with a first surface and at least one transistor group over the first surface. The first surface includes at least one pixel region, and the pixel region includes first transistors arranged in an array. In the same row of first transistors, gates of the first transistors are connected to the same scan line, and sources of the first transistors are connected to different signal lines.

The at least one transistor group includes transistor subgroups arranged in sequence. The transistor subgroups contain second transistors. Within the same transistor group, gates of the second transistors are connected to the same first trace, sources of the second transistors are connected to the same second trace, and drains of the second transistors are connected to the same third trace. The first trace, second trace, and third trace are each connected to at least one solder pad, respectively. The second transistors are arranged in the same layer as the first transistors.

Optionally, at least one side of the pixel region is parallel and opposite to a transistor group. The arrangement direction of the transistor subgroups in the transistor group is parallel to a length direction of a side of the pixel region that is parallel and opposite to the transistor group.

In the thin film transistor panel provided by the present disclosure, the first surface of the substrate includes a pixel region and a transistor group. The pixel region contains first transistors configured in an array. The first transistors may be used to control pixels for image display. The transistor group includes transistor subgroups. The transistor subgroup contains second transistors that are arranged in the same layer as the first transistors. Through the first trace, second trace, and third trace, second transistors in the transistor group may be connected in parallel. Through solder pads connected to the first trace, second trace, and third trace, test signals may be applied to the transistor group, and sampled signals may be obtained. Since the second transistors are arranged in the same layer as the first transistors, the sampled signals obtained from the second transistors may characterize the performance of the first transistors in the pixel region, enabling performance tests of the first transistors to determine whether there is a faulty first transistor in the pixel region.

Additionally, since the transistor group may perform performance testing on the first transistors in the pixel region through sequentially arranged transistor subgroups, along the arrangement direction of the transistor subgroup, second transistors in each transistor subgroup may be used to do performance test on first transistors in an area of the pixel region opposite the second transistors. Therefore, the transistor group may test the performance of the first transistors in a corresponding area of the pixel region by utilizing long-range parallel-connected second transistors along the arrangement direction of the transistor subgroups. The transistor group may test the performance of the first transistors across a larger range in the pixel region, thereby expanding the testing scope and improving the accuracy of performance tests on the first transistors.

To make the aforementioned objectives, features, and advantages of the present disclosure more comprehensible, the following provides a further detailed explanation in conjunction with the accompanying drawings and specific embodiments.

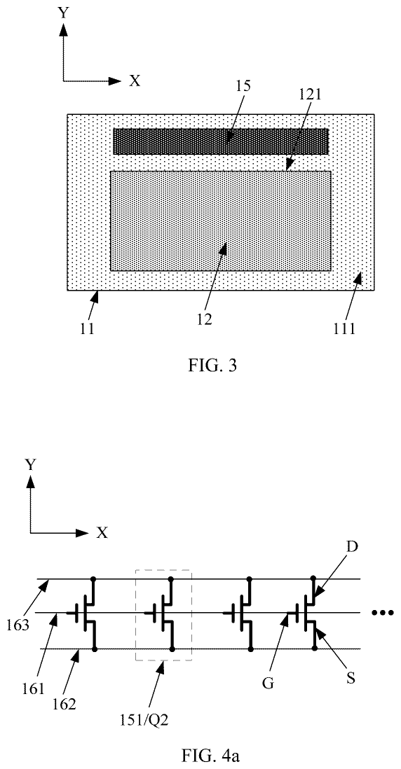

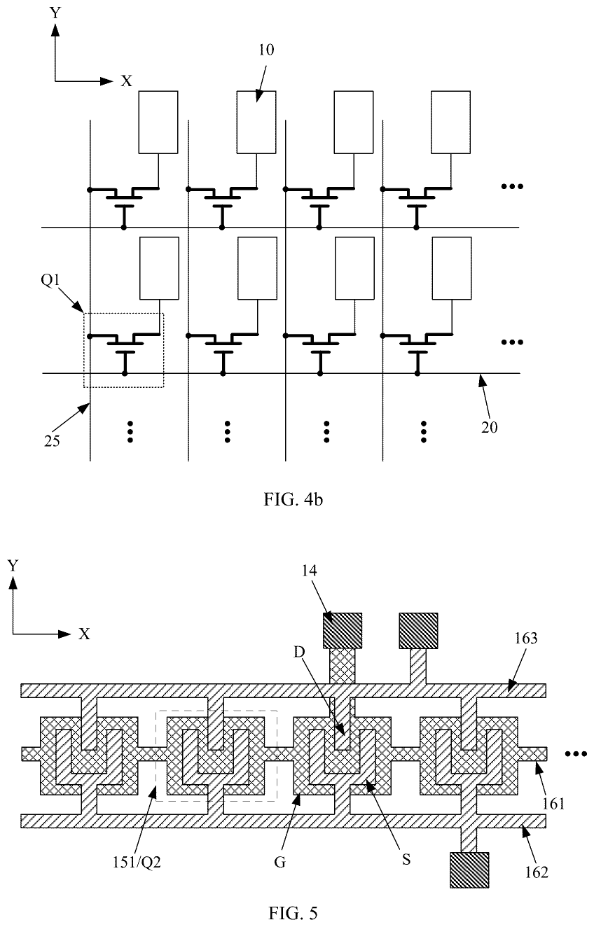

FIG. 3 is a top view of a thin film transistor panel provided by embodiments of the present disclosure. FIG. 4a is an equivalent circuit diagram of a transistor group opposite to a first side edge. FIG. 4b is an equivalent circuit diagram of a row of pixels in a pixel region and first transistors correspondingly connected. FIG. 5 is a layout of a transistor group opposite to the first side edge. In the configurations illustrated in FIGS. 3-5, an LCD display panel is used for illustrative purposes. A pixel array of the display panel includes pixels 10 arranged in an array, with each pixel 10 connected to a corresponding first transistor Q1.

As shown in FIGS. 3-5, the thin film transistor panel includes a substrate 11 with a first surface 111 and at least one transistor group 15 over the first surface 111. The first surface 111 includes at least one pixel region 12, and the pixel region 12 includes first transistors Q1 arranged in an array. In the same row of the first transistors Q1, gates of the first transistors Q1 are connected to the same scan line 20, and sources of the first transistors Q1 are connected to different signal lines 25, respectively. The scan line 20 is used to provide scan signals to the first transistors Q1 to control conduction states of the first transistors Q1.

The transistor group 15 includes transistor subgroups 151 arranged in sequence, and each transistor subgroup 151 contains a second transistor Q2. Within the same transistor group 15, gates G of the second transistors Q2 are connected to the same first trace 161, sources S of the second transistors Q2 are connected to the same second trace 162, and drains D of the second transistors Q2 are connected to the same third trace 163. The first trace 161, second trace 162, and third trace 163 are each connected to at least one solder pad 14. The second transistors Q2 are arranged in the same layer as the first transistors Q1.

At least one side edge of the pixel region 12 is parallel and opposite to a transistor group 15. The arrangement direction of the transistor subgroups 151 in the transistor group 15 is parallel to the length direction of a side edge of the pixel region 12 that is parallel and opposite to the transistor group 15. The second transistor Q2 may have the same structure as the first transistor Q1. Sampled signals obtained from the second transistor Q2 may be used to characterize the performance of the first transistor Q1, thereby enabling performance testing of the first transistor Q1 through the second transistor Q2.

Depending on the function of the first transistor Q1 in a pixel circuit, a signal line 25 may be used to provide the first transistor Q1 with any one of a data signal, a reset signal, or a power supply voltage. The specific signal applied to the signal line 25 is not limited in embodiments of present disclosure. If the display panel is an LCD panel, the signal line 25 may serve as a data line, providing data signals. The drain of the first transistor Q1 may be connected to a pixel electrode of the pixel 10.

In the thin film transistor panel, the second transistors Q2 are arranged in the same layer as the first transistors Q1. The first and second transistors may be fabricated through the same process flow and have identical structures. Therefore, the performance of the first transistor Q1 may be characterized by the second transistor Q2.

Notably, in FIG. 4b, an LCD panel is used as an example to provide a simplified schematic illustration of an equivalent circuit of a pixel 10 and a first transistor Q1 connected to the pixel 10. For other types of display panels, such as LED panels or OLED panels, the structure and layout of the first transistors Q1 in the pixel region 12 and signal line 25 and scan line 20 connected with the first transistors Q1 may refer to existing pixel circuit designs of display panels. The embodiments of present disclosure do not impose limitations on these aspects.

In some embodiments, the thin film transistor panel may be used to fabricate an array substrate of a display panel. The display panel may be an LCD panel, an OLED panel, or an LED panel. The display panel includes a pixel array. The array substrate includes pixel circuits connected to pixels in the pixel array. The pixel circuit may include one or more pixel transistors. Different first transistors in the pixel region 12 are located in different pixel circuits.

Optionally, both the first transistor Q1 and second transistor Q2 are indium gallium zinc oxide (IGZO) transistors. The performance of IGZO transistors in the pixel region 12 may be tested using second transistors Q2 in the transistor group 15. In this case, the pixel circuit includes at least one IGZO transistor. An IGZO transistor from each pixel circuit forms the first transistors Q1 arranged in an array in the pixel region 12.

In other configurations, both the first transistor Q1 and the second transistor Q2 may also be low temperature poly-silicon (LTPS) transistors. The performance of the LTPS transistors in the pixel region 12 may be tested using the second transistor Q2 in the transistor group 15. In this case, the pixel circuit includes at least one LTPS transistor, and one LTPS transistor from each pixel circuit forms the first transistors Q1 arranged in an array in the pixel region 12.

In some embodiments, the first transistor Q1 and second transistor Q2 may both be amorphous silicon (a-Si) transistors. The performance of the a-Si transistors in the pixel region 12 may be tested through the second transistors Q2 in the transistor group 15. At this time, the pixel circuit includes at least one a-Si transistor. One a-Si transistor in each pixel circuit forms the first transistors Q1 arranged in arrays in the pixel region 12.

In some embodiments, a transistor group 15 may be arranged opposite to a side edge of the pixel region 12, or one transistor group 15 may be arranged opposite to each of multiple side edges, respectively. In the same transistor group 15, the first trace 161, the second trace 162, and the third trace 163 may be arranged in parallel, with their extension directions parallel to the arrangement direction of the transistor subgroups 151 in the transistor group 15.

The row direction X and column direction Y of the array where the first transistors Q1 are located are both parallel to the first surface 111. In the configuration shown in FIG. 3, the transistor group 15 is arranged opposite to a first side edge 121 in the pixel region 12 as an illustrative example. The length direction of the first side edge 121 may be parallel to the row direction X. In the transistor group 15 correspondingly configured, each transistor subgroup 151 is sequentially arranged along the row direction X. The first trace 161, the second trace 162, and the third trace 163 all extend along the row direction X. In some other cases, the length direction of the first side edge 121 may also be parallel to the column direction Y.

In a thin film transistor panel in some embodiments, a first surface 111 of a substrate 11 includes a pixel region 12 and a transistor group 15. The pixel region 12 is provided with first transistors Q1 arranged in an array. The first transistors Q1 may be used to control pixels for image display. The transistor group 15 includes transistor subgroups 151. Each transistor subgroup 151 contains second transistors Q2 arranged in the same layer as the first transistors Q1. Through the first trace 161, the second trace 162, and the third trace 163, second transistors Q2 in the transistor group 15 may be connected in parallel. Through solder pads 14 connected to the first trace 161, the second trace 162, and the third trace 163, test signals may be applied to the transistor group 15, and sampled signals may be obtained. Since the second transistors Q2 are arranged in the same layer as the first transistors Q1, sampled signals obtained from the second transistors Q2 may characterize the performance of the first transistors in the pixel region. It enables performance testing of the first transistors Q1 to determine whether there is a faulty first transistor Q1 in the pixel region.

Moreover, since the transistor group 15 may perform performance testing on the first transistors Q1 in the pixel region through sequentially arranged transistor subgroups 151, along the arrangement direction of the transistor subgroups 151, the second transistors Q2 in each transistor subgroup 151 may be used to test the performance of the first transistors Q1 in corresponding regions of the pixel region 12. Therefore, the transistor group 15 may test the performance of the first transistors Q1 in corresponding regions of the pixel region 12 by utilizing long-range parallel-connected second transistors Q2 along the arrangement direction of the transistor subgroups 151. The transistor group 15 may test the performance of the first transistors Q1 across a larger range in the pixel region 12, thereby expanding the testing scope and improving the accuracy of the performance testing on the first transistors Q1.

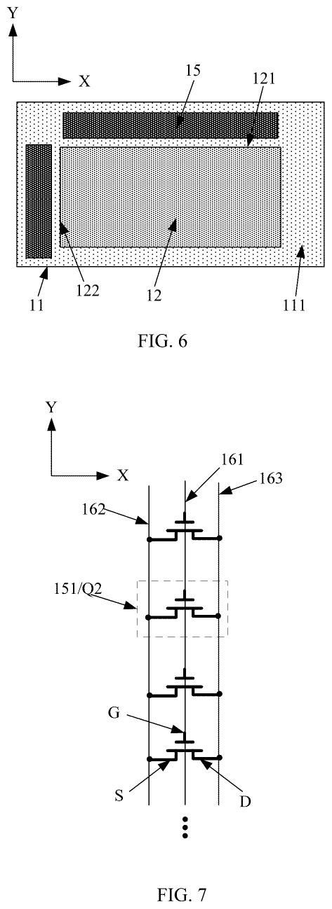

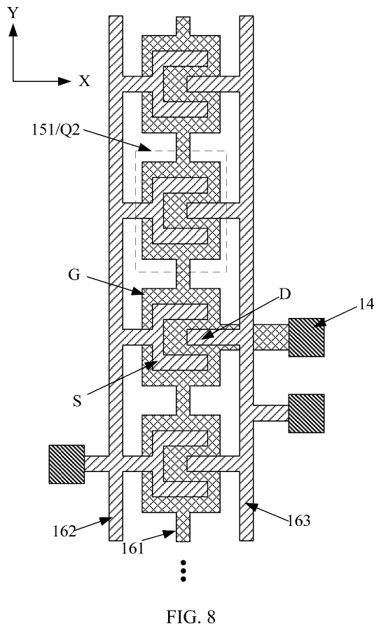

FIG. 6 is a top view of another thin film transistor panel provided by embodiments of the present disclosure. FIG. 7 is a layout of a transistor group opposite to a second side edge. FIG. 8 is an equivalent circuit diagram of the transistor group opposite to the second side edge. In some embodiments, the thin film transistor panel shown in FIGS. 6-8 includes a pixel region 12 that has a first side edge 121 and a second side edge 122. The first side edge 121 is parallel to a row direction X of an array and the second side edge 122 is parallel to a column direction Y of the array. The first side edge 121 and second side edge 122 are each provided with a parallel and opposite transistor groups 15. The layout and equivalent circuit diagram of the transistor group 15 opposite to the first side edge 121 may be referred to that shown in FIGS. 4a and 5.

In the configuration shown in FIGS. 6-8, a transistor group 15 is arranged opposite to each of the first side edge 121 and the second side edge 122 of the pixel region 12. Through the transistor group 15 opposite to the first side edge 121, each transistor subgroup 151 may perform performance testing on first transistors Q1 in a corresponding region of the pixel region 12 along the row direction X. Similarly, through the transistor group 15 opposite to the second side edge 122, each transistor subgroup 151 may perform performance testing on the first transistors Q1 in a corresponding region of the pixel region 12 along the column direction Y. By utilizing the transistor groups 15 arranged respectively opposite to the first side edge 121 and the second side edge 122, the location of a faulty first transistor Q1 in the pixel region 12 may be accurately identified.

For example, the pixel region 12 contains first transistors Q1 arranged in m rows and n columns, where both m and n are positive integers greater than 1. When a faulty transistor is detected in the i-th column by a transistor group 15 opposite to the first side edge 121, and a faulty transistor is detected in the j-th row by a transistor group 15 opposite to the second side edge 122, test results from the two transistor groups 15 intersect horizontally and vertically. It may be determined that a first transistor Q1 located at the i-th column and j-th row in the pixel region 12 is faulty. Here, i is a positive integer not greater than n, and j is a positive integer not greater than m.

FIG. 9 is a top view of yet another thin film transistor panel provided by embodiments of the present disclosure. Based on the aforementioned implementation, in the thin film transistor panel shown in FIG. 9, the pixel region 12 further includes a third side edge 123 opposite to the first side edge 121 and a fourth side edge 124 opposite to the second side edge 122. At least one of the third side edge 123 and the fourth side edge 124 is provided with a transistor group 15. The transistor group 15 is arranged parallel and opposite to the third side edge 123 or fourth side edge 124.

In FIG. 9, an example is illustrated where both the third side edge 123 and the fourth side edge 124 have a transistor group 15 arranged opposite to them. In other configurations, it is also possible to arrange a transistor group 15 parallel and opposite to only one of the third side edge 123 or the fourth side edge 124.

The transistor group 15 arranged opposite to the third side edge 123 may have the same layout and equivalent circuit diagram as the transistor group 15 arranged opposite to the first side edge 121. If a transistor group 15 is arranged opposite to the third side edge 123, its equivalent circuit diagram and layout may be referred to that shown in FIGS. 4a and 5 of the aforementioned embodiments.

Similarly, the transistor group 15 arranged opposite to the fourth side edge 124 may have the same layout and equivalent circuit diagram as the transistor group 15 arranged opposite to the second side edge 122. If a transistor group 15 is arranged opposite to the fourth side edge 124, its equivalent circuit diagram and layout may be referred to that shown in FIGS. 7 and 8 of the aforementioned embodiments.

For a transistor group 15 opposite to the first side edge 121, since the third side edge 123 is away from the transistor group 15, the testing accuracy of the transistor group 15 for first transistors Q1 near the third side edge 123 is relatively low. When transistor groups 15 are respectively arranged opposite to both the first side edge 121 and the third side edge 123, the transistor group 15 opposite to the third side edge 123 may accurately test the performance of first transistors Q1 near the third side edge 123. It improves the testing accuracy of transistor groups 15 for first transistors Q1 located at the opposite edges of the pixel region 12 along the column direction Y.

Similarly, for a transistor group 15 opposite to the second side edge 122, since the fourth side edge 124 is away from this transistor group 15, the testing accuracy of this transistor group 15 for first transistors Q1 near the fourth side edge 124 is relatively low. When transistor groups 15 are respectively arranged opposite to both the second side edge 122 and the fourth side edge 124, the transistor group 15 opposite to the fourth side edge 124 may accurately test the performance of first transistors Q1 near the fourth side edge 124. It improves the testing accuracy of the transistor groups 15 for first transistors Q1 located at the opposite edges of the pixel region 12 along the row direction X.

As described above, the pixel region 12 may be configured to have first transistors Q1 arranged in m rows and n columns, where both m and n are positive integers greater than 1. If a transistor group 15 is arranged parallel and opposite to a side edge of the pixel region 12 extending along the row direction X, the transistor group 15 has n transistor subgroups, with each transistor subgroup 151 corresponding to one column of the first transistors Q1. If a transistor group 15 is arranged parallel and opposite to a side edge of the pixel region 12 extending along the column direction Y, the transistor group 15 has m transistor subgroups, with each transistor subgroup 151 corresponding to one row of the first transistors Q1.

For a side edge extending along the row direction X (such as the first side edge 121 or the third side edge 123), a transistor group 15 opposite to this side edge has n transistor subgroups. This makes that each column of the first transistors Q1 in the pixel region 12 is arranged opposite to a corresponding transistor subgroup 151 in the transistor group 15 along the column direction Y. Performance testing may be conducted on each column of the first transistors Q1 using an opposite transistor subgroup 151 in the transistor group 15, thereby improving the accuracy of the performance testing on the first transistors Q1.

Similarly, for a side edge extending along the column direction Y (such as the second side edge 122 or the fourth side edge 124), a transistor group 15 opposite to this side edge has m transistor subgroups. This makes that each row of the first transistors Q1 in the pixel region 12 is arranged opposite to a corresponding transistor subgroup 151 in the transistor group 15 along the row direction X. Performance testing on each row of the first transistors Q1 may be conducted using the opposite transistor subgroup 151 in the transistor group 15, thereby improving the accuracy of the performance testing on the first transistors Q1.

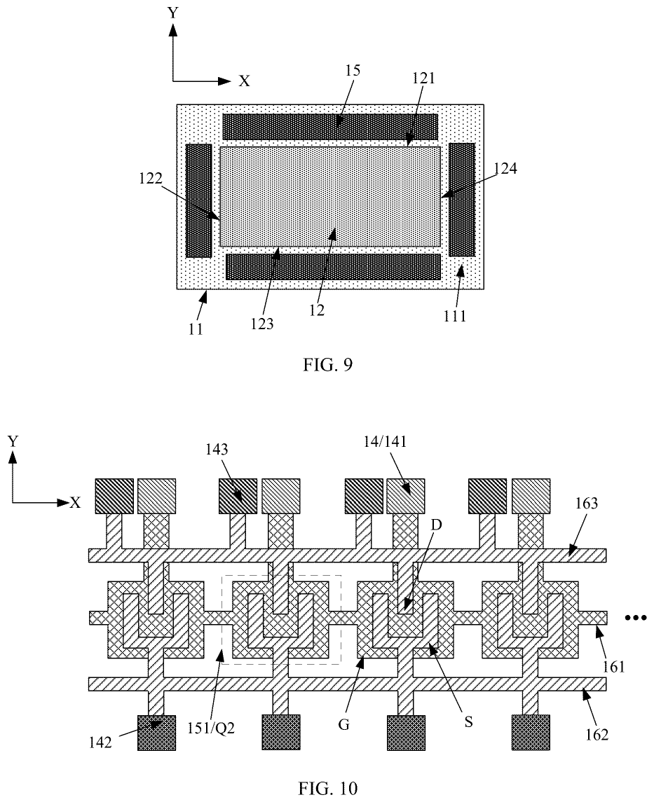

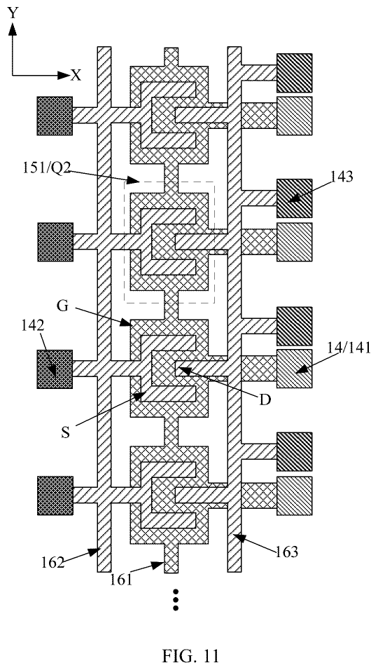

Optionally, as shown in FIG. 10 or 11, in the same transistor group 15, the first trace 161, the second trace 162, and the third trace 163 all extend along the arrangement direction of the transistor subgroups 151. The solder pads 14 connected to the first trace 161, the second trace 162, and the third trace 163 are sequentially the first solder pad 141, the second solder pad 142, and the third solder pad 143. Along the arrangement direction, multiple different positions of the first trace 161 are connected to the first pad 141, multiple different positions of the second trace 162 are connected to the second solder pad 142, and multiple different positions of the third trace 163 are connected to the third solder pad 143. In this configuration, each trace is connected to multiple solder pads 14, allowing the same trace to input test signals at different positions or output sampled signals at different positions. This facilitates performance testing of the first transistors Q1 in the pixel region 12 through the second transistors Q2.

In some embodiments, the solder pads 14 may be arranged in the same metal layer as the connected traces, and the solder pads 14 and the connected traces may form an integrated structure. For example, the first solder pad 141 and the first trace 161 are located in the same metal layer, the second solder pad 142 and the second trace 162 are located in the same metal layer, and the third solder pad 143 and the third trace 163 are located in the same metal layer. Optionally, the first trace 161, the second trace 162, and the third trace 163 may be arranged in the same metal layer. In some other embodiments, at least two of the first trace 161, the second trace 162, and the third trace163 may be located in different layers.

FIG. 10 is a layout of a transistor group arranged parallel and opposite to the pixel region along the column direction provided by embodiments of the present disclosure. In some embodiments, for the same transistor group 15, the arrangement direction of the transistor subgroups 151 is parallel to the row direction X. The transistor group 15 may be arranged parallel and opposite to the first side edge 121 or the third side edge 123. In the transistor group 15, the first trace 161, the second trace 162, and the third trace 163 all extend along the row direction X. Along the row direction X, positions on the first trace 161 are connected to the first solder pad 141, respectively. Positions of the second trace 162 are connected to the second solder pad 142, respectively. Positions of the third trace 163 are connected to the third solder pad 143, respectively.

FIG. 11 is a layout of a transistor group arranged parallel and opposite to a pixel region along the row direction provided by embodiments of the present disclosure. In some embodiments, for the same transistor group 15, the arrangement direction of transistor subgroups 151 is parallel to the column direction Y. The transistor group 15 may be arranged parallel and opposite to the second side edge 122 or the fourth side edge 124. In the transistor group 15, the first trace 161, the second trace 162, and the third trace 163 all extend along the column direction Y. Along the column direction Y, positions on the first trace 161 are connected to the first solder pad 141, positions of the second trace 162 are connected to the second solder pad 142, and positions of the third trace 163 are connected to the third solder pad 143.

Optionally, for the same transistor group 15, along the arrangement direction, the transistor subgroups 151 are correspondingly connected to a first solder pad 141, a second solder pad 142, and a third solder pad 143, respectively. In this implementation, as shown in FIG. 9 or 10, for the same transistor group 15, the first trace 161 may be configured to have first pads 141 corresponding with the transistor subgroups 151 in a one-to-one manner, the second trace 162 may be configured to have second pads 142 corresponding with the transistor subgroups 151 in a one-to-one manner, and the third trace 163 may be configured to have third pads 143 corresponding with the transistor subgroups 151 in a one-to-one manner. In this case, when the first transistors Q1 are tested through the transistor group 15, if sampled signals indicate the presence of a faulty first transistor Q1 in the pixel region 12, a binary test method may be applied multiple times to repeatedly divide and test the transistor group 15, thereby determining the location of a faulty first transistor Q1 in the pixel region 12.

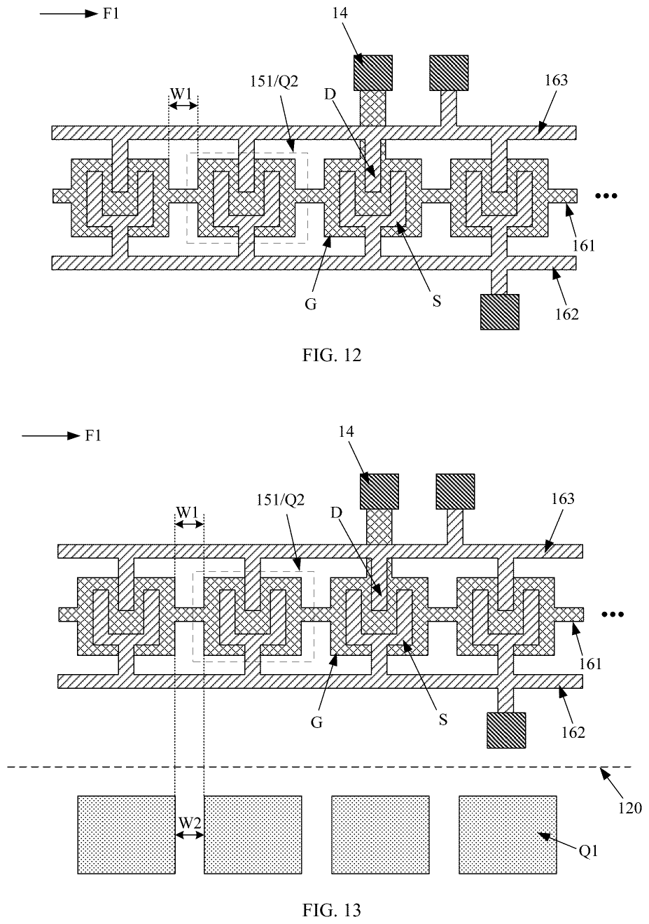

FIG. 12 is a top view of yet another thin film transistor panel provided by embodiments of the present disclosure. Based on the aforementioned embodiments, in a thin film transistor panel shown in FIG. 12, for the same transistor group 15, adjacent transistor subgroups 151 are spaced apart by a preset distance W1 along the arrangement direction. In the same transistor group 15, the arrangement direction of the transistor subgroups 151 is defined as a first arrangement direction F1. Based on the preset distance W1, the transistor group 15 may be cut at positions corresponding to the preset distance W1. Optionally, the preset distance W1 may be greater than 3 μm. Here, if the transistor group 15 is arranged parallel and opposite to a side edge of the pixel region 12 parallel to the row direction X, the arrangement direction F1 is parallel to the row direction X. If the transistor group 15 is arranged parallel and opposite to a side edge of the pixel region 12 parallel to the column direction Y, the arrangement direction F1 is parallel to the column direction Y.

For the same transistor group 15, when it is determined whether there is a faulty first transistor Q1 in the pixel region 12 through the transistor group 15, the transistor group 15 may be cut into two parts using the preset distance W1 between two adjacent transistor subgroups 151. Then, the two parts of the transistor group 15 may be tested separately to determine the location of a faulty first transistor Q1 in the pixel region 12. The first trace 161, the second trace 162, and the third trace 163 may all be cut using the preset distance W1 to achieve the purpose of dividing the transistor group 15.

In some embodiments, setting the preset distance W1 to be greater than 3 μm leaves a sufficient cutting space between adjacent transistor subgroups 151, making it easier to divide the transistor group 15 using the preset distance W1.

Currently, laser cutting is widely used in the field of display panel fabrication. In some embodiments, when performance testing on the first transistors Q1 is conducted, the transistor group may be divided by laser cutting. Specifically, using the preset distance W1 between adjacent transistor subgroups 151, the first trace 161, the second trace 162, and the third trace 163 are all cut by a laser. Setting the preset distance W1 to be greater than 3 μm leaves a sufficient laser cutting space between adjacent transistor subgroups 151, making it easier for a laser to divide the transistor group 15 based on the preset distance W1.

FIG. 13 is a top view of a partial region of a thin film transistor panel provided by embodiments of the present disclosure. Based on the aforementioned embodiments, in the configuration shown in FIG. 13, a preset distance W1 is equal to a spacing W2 between two adjacent first transistors Q1 along the arrangement direction. In this configuration, along the arrangement direction, the preset distance W1 between adjacent transistor subgroups 151 is set equal to the spacing W2 between adjacent first transistors Q1. The first transistors Q1 may be arranged corresponding to the transistor subgroups 151 in a one-to-one manner along the arrangement direction. The location of a faulty first transistor Q1 may be accurately detected through the transistor subgroups 151 that correspond to the first transistor Q1 in a one-to-one manner.

In FIG. 13, the arrangement direction of the transistor subgroups 151 is parallel to the target side edge 120 of the pixel region 12. If the target side edge 120 is parallel to the row direction X, the target side edge 120 may be the first side edge 121 or the third side edge 123, and the arrangement direction is parallel to the row direction X. If the target side edge 120 is parallel to the column direction Y, the target side edge 120 may be the second side edge 122 or the fourth side edge 124, and the arrangement direction is parallel to the column direction Y.

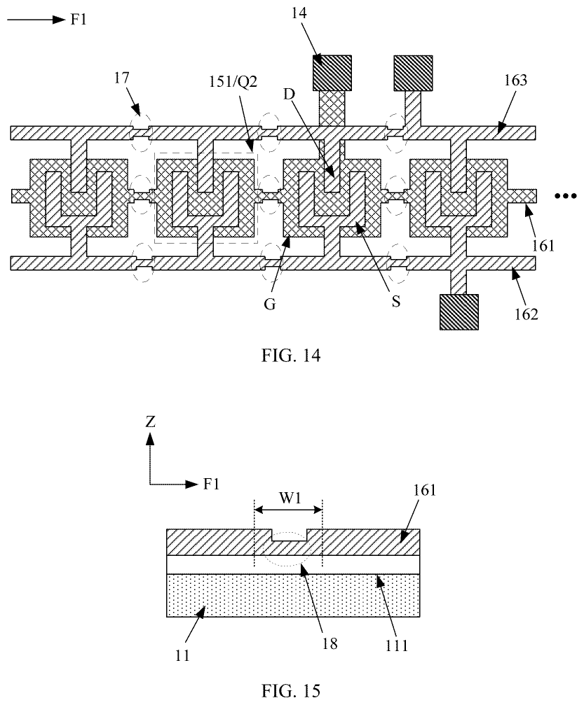

FIG. 14 is a top view of yet another thin film transistor panel provided by embodiments of the present disclosure. Based on the aforementioned embodiments, in the thin film transistor panel shown in FIG. 14, for the same transistor group 15, and in a region of the preset distance W1, the first trace 161, the second trace 162, and the third trace 163 are all provided with a cutting position 17. The line width at the cutting position is smaller than the line width outside the cutting position. In this configuration, through the cutting positions 17, it is convenient to locate dividing positions when the transistor group 15 is divided. With a smaller line width at the cutting position 17, it also facilitates the division of the transistor group 15.

FIG. 15 is a cross-sectional view of a transistor group at a trace position provided by embodiments of the present disclosure. FIG. 15 illustrates an example where a first trace 161 has a set position 18. FIG. 15 shows a partial cross-sectional view of the first trace 161 along the length direction in a region of a preset distance W1. The cross-section shown in FIG. 15 is parallel to the arrangement direction of the transistor subgroups 151 in the transistor group 15 and parallel to a first direction Z. The first direction Z is perpendicular to the first surface 111.

In the configuration shown in FIG. 15, within a region of the preset distance W1, at least one of the first trace 161, the second trace 162, and the third trace 163 has a set position 18. The trace thickness at the set position 18 is smaller than the trace thickness outside the set position 18. Optionally, the first trace 161, the second trace 162, and the third trace 163 may each be provided with a set position 18 in a region of the preset distance W1.

Optionally, for a trace with a set position 18, a groove may be provided at the set position 18 on a side of the trace facing away from the substrate 11. As such, the trace thickness at the set position 18 is smaller than the trace thickness outside the set position 18.

In the configuration shown in FIG. 15, the set position 18 with a smaller trace thickness facilitates locating of a division point when the transistor group 15 is divided. The smaller trace thickness at the set position 18 also makes it easier to divide the transistor group 15.

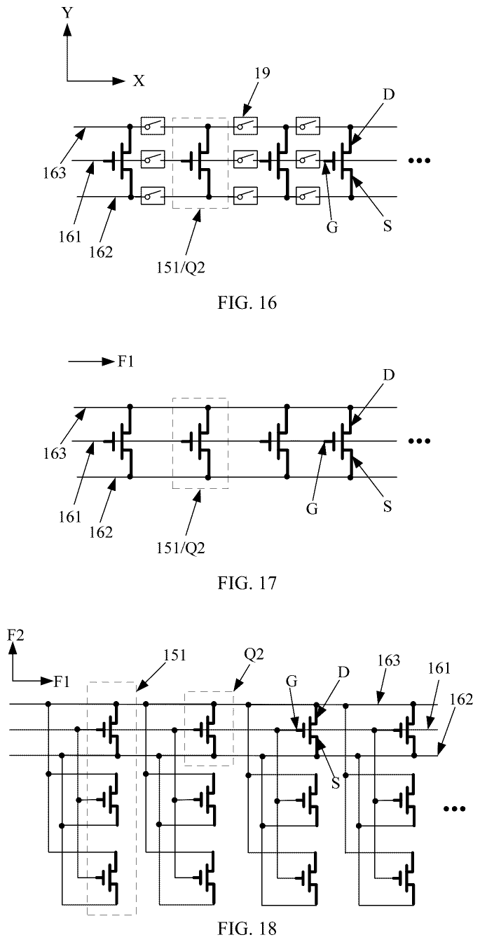

FIG. 16 is an equivalent circuit diagram of a transistor group provided by embodiments of the present disclosure. For the same transistor group 15, adjacent transistor subgroups 151 are connected in parallel through control switches 19. The control switches 19 allow the transistor group 15 to be disconnected at different positions. During performance testing on the first transistors Q1 using the transistor group 15, the transistor group 15 may be disconnected at desired positions by controlling the switches 19, eliminating the need for physical division of the transistor group 15.

In FIG. 16, an example is illustrated where the transistor group 15 is arranged parallel and opposite to a side edge whose length direction is parallel to the row direction X in the pixel region 12. In this case, the arrangement direction of the transistor subgroups 151 is parallel to the row direction X. For a transistor group 15 arranged parallel and opposite to a side edge whose length direction is parallel to the column direction Y in the pixel region 12, adjacent transistor subgroups 151 may also be connected in parallel through control switches 19, as shown in FIG. 16.

Optionally, for the same transistor group 15, at least one of the first trace 161, the second trace 162, and the third trace 163 between adjacent transistor subgroups 151 may be provided with a control switch 19. Alternatively, it may be configured that the first trace 161, the second trace 162, and the third trace 163 between adjacent transistor subgroups 151 are all provided with a control switch 19, respectively. In such cases, by placing control switches 19 in each trace at positions between adjacent transistor subgroups 151, the transistor group 15 may be disconnected between any two transistor subgroups 151 through a corresponding control switch 19. It facilitates accurate locating of a faulty first transistor Q1 in the pixel region 12 through the binary test method.

FIG. 17 is an equivalent circuit diagram of another transistor group provided by embodiments of the present disclosure. Based on the aforementioned embodiments, as shown in FIG. 17, a transistor subgroup 151 including a second transistor Q2 is provided. For the same transistor group 15, it includes a row of second transistors Q2 arranged sequentially along the arrangement direction. The circuit structure of the transistor group 15 is simple, which facilitates the fabrication processes of thin film transistor panels.

FIG. 18 is an equivalent circuit diagram of another transistor group provided by embodiments of the present disclosure. Based on the aforementioned embodiments, as shown in FIG. 18, the transistor subgroup 151 includes second transistors Q2 arranged in sequence. For the same transistor group 15, the arrangement direction of the second transistors Q2 in the transistor subgroup 151 is perpendicular to the arrangement direction of the transistor subgroups in the transistor group 15. In the same transistor subgroup 151, the arrangement direction of the second transistors Q2 is a second arrangement direction F2. In the same transistor group 15, a first arrangement direction F1 is perpendicular to the second arrangement direction F2, and both are parallel to the first surface 111.

As shown in FIG. 18, the transistor subgroup 151 is configured to include second transistors Q2 arranged in sequence. In the same transistor subgroup 151, gates G of each second transistor Q2 are connected to the first trace 161, sources S are connected to the second trace 162, and drains D are connected to the third trace 163. The second transistors Q2 may be connected in parallel. The currents in each second transistor Q2 may be superimposed to improve the current capability. The on-resistance may be reduced, the test power consumption may be decreased, and the test sensitivity of the transistor group 15 may be improved.

Based on the aforementioned embodiments, in a thin film transistor panel, it may be configured that the shape of the second transistor Q2 is the same as that of the first transistor Q1, and the spacing between adjacent second transistors Q2 is the same as that between adjacent first transistors Q1. If the transistor group 15 is parallel to a side edge of the pixel region 12 that extends in the row direction X, the spacing between adjacent second transistors Q2 in the transistor group 15 is the same as that between adjacent first transistors Q1 along the row direction X. If the transistor group 15 is parallel to a side edge extending along the column direction Y in the pixel region 12, the spacing between adjacent second transistors Q2 in the transistor group 15 is the same as that between adjacent first transistors Q1 along the column direction Y. In this configuration, it is arranged that the spacing of the second transistors Q2 in the transistor group 15 is the same as the spacing of the first transistors Q1 in the pixel region 12. The first transistor Q1 may be better characterized by the second transistor Q2, so that the performance of the first transistor Q1 may be more accurately tested by the second transistor Q2.

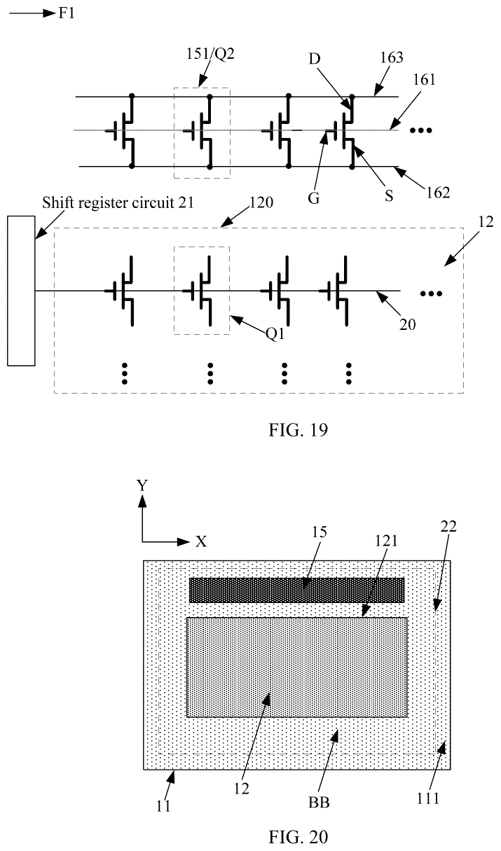

FIG. 19 is an equivalent circuit diagram of a thin film transistor panel provided by embodiments of the present disclosure. FIG. 19 shows a row of first transistors Q1 adjacent to a target side edge 120 in the pixel region 12 and a transistor group 15 arranged parallel and opposite to the target side edge 120. The transistor group 15 includes second transistors Q2 arranged sequentially along a first arrangement direction F1. The first trace 161, the second trace 162, and the third trace 163 in the transistor group 15 are all floating. The first transistors Q1 are connected to a shift register circuit 21 via a scan line 20. In other configurations, the first transistors Q1 may also be directly connected to a driving circuit (e.g., a gate driver chip) through the scan line 20.

In the configuration shown in FIG. 19, the first trace 161, the second trace 162, and the third trace 163 are all floating. When the first transistors Q1 is tested through the transistor group 15, test signals may be applied to the transistor group 15 and sampled signals may be obtained via solder pads 14 connected to each trace. This eliminates the need to set up a test signal input circuit connected to the transistor group 15 in the thin film transistor panel, thereby avoiding taking an additional layout space on the panel.

Moreover, compared to directly setting up a test signal input circuit connected to the transistor group 15 in the panel, the approach in the present disclosure, which uses solder pads 14 to input test signals and output sampled signals, is not constrained by the layout position of the test signal input circuit. This facilitates tests on the first transistors Q1 using the binary test method and allows cutting the transistor group 15 as needed.

FIG. 20 is a top view of yet another thin film transistor panel provided by embodiments of the present disclosure. Based on the aforementioned embodiments, in the configuration shown in FIG. 20, a first surface 111 includes at least one panel region 22. The panel region 22 contains a pixel region 12 and a border area BB surrounding the pixel region 12. For the same panel region 22, a transistor group 15 is arranged parallel and opposite to a side edge of the pixel region 12 and is located in the border area BB. In FIG. 20, an example is illustrated where a first side edge 121 of the pixel region 12 is parallel and opposite to the transistor group 15. As described earlier, there may be transistor groups 15 arranged parallel and opposite to other side edges of the pixel region 12. The panel region 22 may be used to fabricate an array substrate of a display panel.

When the border area BB of the panel region 22 has a sufficient space, the transistor group 15 may be arranged in the border area BB of the panel region 22, as shown in FIG. 20. Certain redundant space in the border area BB may be utilized for laying out the transistor group 15 to test the first transistors Q1. The transistor group 15 may be positioned close to the pixel region 12, facilitating more accurate tests of the first transistors Q1 through the second transistors Q2.

FIG. 21 is a top view of yet another thin film transistor panel provided by embodiments of the present disclosure. Based on the aforementioned embodiments, in the configuration shown in FIG. 21, a border area BB includes a first region 221 surrounding a pixel region 12 and a second region 222 surrounding the first region 221. The first region 221 is used to arrange dummy pixels and dummy pixel circuits corresponding to the dummy pixels. The pixel region 12 is provided with display pixels and pixel circuits connected to the display pixels. The pixel circuits including first transistors Q1. A transistor group 15 is located in the first region 221. Thin film transistors in the dummy pixel circuits serve as second transistors Q2. The dummy pixels and dummy pixel circuits are disconnected.

FIG. 21 does not show display pixel regions in the pixel region 12 and first transistors Q1 connected to the display pixel regions, nor does it show the dummy pixels in the first region 221 and dummy pixel circuits connected to the dummy pixels. These structures may be the same as those in existing display panels, and are not elaborated further.

In the configuration shown in FIG. 21, reusing transistors in the dummy pixel circuits as second transistors Q2 allows the transistor group 15 to be arranged in the first region 221, minimizing the distance between the second transistors Q2 and the pixel region 12. This facilitates more accurate testing of the first transistors Q1 through the second transistors Q2. Additionally, since transistors in the dummy pixel circuits are reused as the second transistors Q2, there is no need to fabricate the second transistors Q2 separately and allocate additional layout space.

When the transistor group 15 is arranged in the border area BB, the transistor group 15 is not limited to the first region 221. In other configurations, the transistor group 15 may also be placed in the second region 222. This approach utilizes the second region 222 in the border area BB, which is located outside the dummy pixel circuits, to lay out the transistor group 15. The redundant space in the second region 222 is used to arrange the transistor group 15 for performing performance tests on the first transistors Q1 in the pixel region 12.

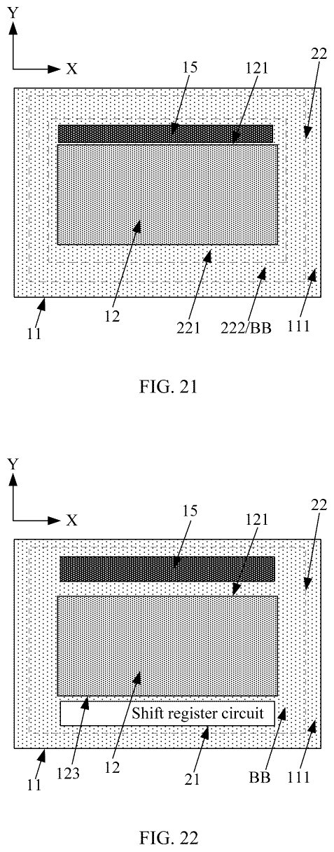

FIG. 22 is a top view of yet another thin film transistor panel provided by embodiments of the present disclosure. Based on the aforementioned embodiments, in the configuration shown in FIG. 22, a shift register circuit 21 is disposed in a border area BB on a side of the pixel region 12, while a transistor group 15 is disposed in the border area BB on the opposite side of the pixel region 12. In FIG. 22, an example is illustrated where the transistor group 15 is arranged adjacent to the first side edge 121 of the pixel region 12 in the border area BB. The transistor group 15 is arranged parallel and opposite to the first side edge 121. Correspondingly, the shift register circuit 21 is arranged adjacent to the third side edge 123 in the border area BB.

In the configuration shown in FIG. 22, the transistor group 15 and the shift register circuit 21 are arranging on opposite sides of the pixel region 12 in the border area BB, avoiding issues that may arise when both are located on the same side of the pixel region 12. In the latter case, since the transistor group 15 is positioned between the shift register circuit 21 and the pixel region 12, the shift register circuit 21 may require rerouting to connect to the first transistors Q1.

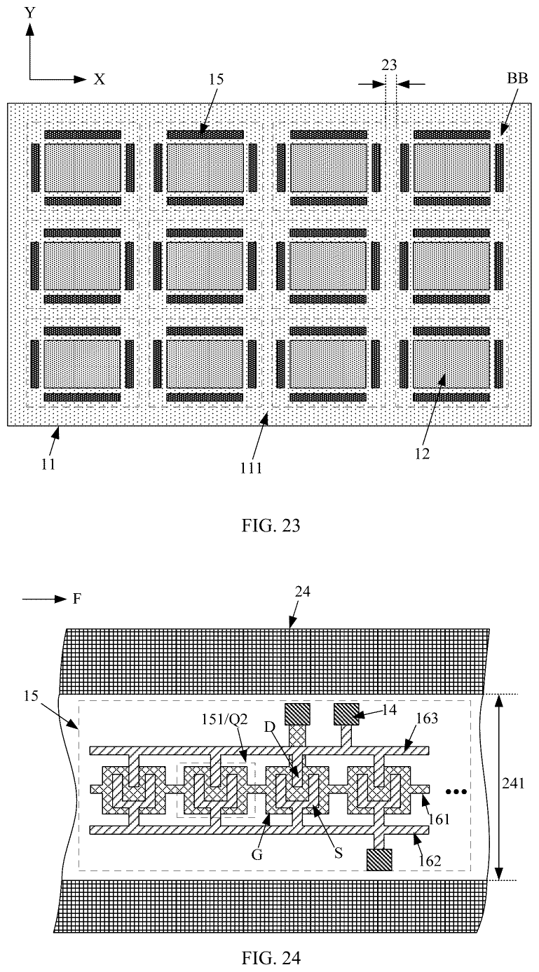

FIG. 23 is a top view of yet another thin film transistor panel provided by embodiments of the present disclosure. Based on the aforementioned embodiments, in the configuration shown in FIG. 23, a first surface 111 includes panel regions 22 arranged in an array. Adjacent panel regions 22 are separated by spacing areas 23. Spacing areas 23 are configured between two adjacent panel regions 22 in the row direction X and between two adjacent panel regions 22 in the column direction Y. Border areas BB of the panel regions 22 are provided with transistor groups 15.

As described above, each panel region 22 is used to fabricate an array substrate of a display panel. The panel region 22 includes a pixel region 12 and a border area BB surrounding the pixel region 12. In the configuration shown in FIG. 23, based on a large-sized thin film transistor panel, cutting along the spacing regions 23 may form multiple array substrates.

In the configuration shown in FIG. 23, since a transistor group 15 for each pixel region 12 is located in the border area BB of a corresponding panel region 22, each pixel region 12 needs to have a transistor group 15 arranged in its border area BB to perform performance tests on first transistors Q1 in the pixel region.

In FIG. 23, an example is illustrated where four side edges of the pixel region 12 are provided with a parallel and opposite transistor group 15, respectively. In this case, four transistor groups 15 are arranged in the border area BB of each panel region 22. In some other configurations, the transistor group 15 may be arranged in only one side border area BB, only two side border areas BB, or only three side border areas BB of the panel region 22.

Based on the aforementioned embodiments, when the transistor group 15 is located in the border area BB of the panel region 22, the structure of the thin film transistor panel may also be that shown in FIG. 24.

FIG. 24 is a top view of yet another thin film transistor panel provided by embodiments of the present disclosure. Based on the aforementioned embodiments, in the configuration shown in FIG. 24, a border area BB of a panel region 22 has a fourth trace 24 surrounding a pixel region 12. The fourth trace 24 is used to supply a fixed voltage. The fourth trace 24 has a hollow region 241. A transistor group 15 is located in this hollow region. In FIG. 24, for illustrative purposes, only one end of the fourth trace 24 in a local border area BB on one side of the pixel region 12 is used as an example for illustration.

The fourth trace 24 may be a common voltage trace, used to supply the common voltage. Taking an LCD panel as an example. Around the edges of its border area BB, a common voltage trace surrounding a pixel region 12 is arranged to provide the common voltage. Since the common voltage trace has a relatively large width, it may be designed with hollowed-out regions. By utilizing a hollowed-out region 241 in a common voltage trace to lay out the transistor group 15, the transistor group 15 does not need to occupy additional panel space, thereby saving space on the panel.

FIG. 25 is a top view of yet another thin film transistor panel provided by embodiments of the present disclosure. Based on the aforementioned embodiments, in the configuration shown in FIG. 25, a first surface 111 includes at least one panel area 22. The panel area 22 includes a pixel region 12 and a border area BB surrounding the pixel region. The transistor group 15 is located outside the border area BB. For products with a small layout space in the border area BB, this method arranges the transistor group 15 outside the panel area 22 without occupying the layout space of the panel area 22.

In the configuration shown in FIG. 25, an example is illustrated where a first side edge 121 has a transistor group 15 arranged parallel and opposite to it. The transistor group 15 is located outside the panel region 22. As described above, other side edges of the pixel region 12 may also have a parallel and opposite transistor group 15. All transistor groups 15 arranged parallel and opposite to the side edges are located outside the panel region 22.

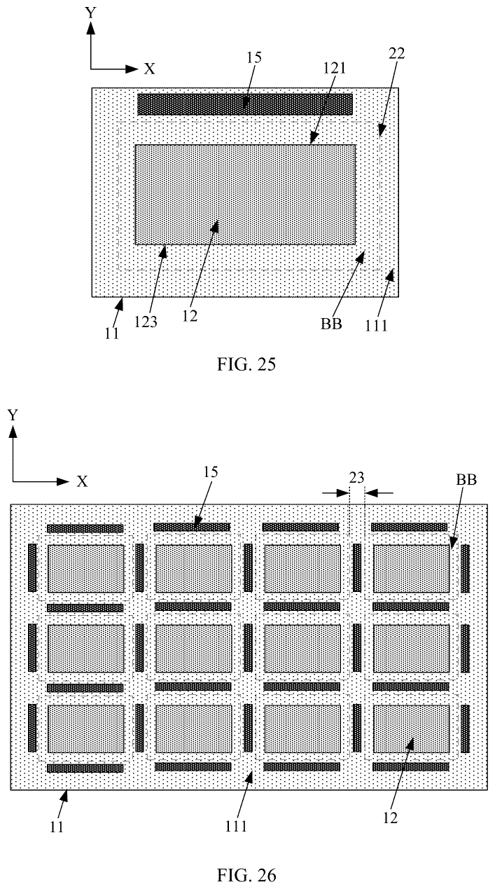

FIG. 26 is a top view of yet another thin film transistor panel provided by embodiments of the present disclosure. Based on the aforementioned embodiments, in the configuration shown in FIG. 26, when there are panel regions 22, there are spacing areas 23 between adjacent panel regions 22, and transistor groups are arranged in the spacing areas 23. Adjacent panel regions 22 may share the same transistor group 15. In this configuration, based on a large-sized thin film transistor panel, dividing along the spacing regions 23 may form multiple array substrates.

In the configuration shown in FIG. 26, since transistor groups 15 arranged parallel and opposite to the side edges of the pixel regions 12 are located outside the panel region 22, the spacing area 23 between adjacent panel regions 22 may be utilized to lay out the transistor group 15. It avoids occupying layout space in the panel region 22.

In some embodiments, if the transistor group 15 is located in the border area BB, after completing the testing of the first transistors Q1 through the second transistors Q2, the transistor group 15 remains in the border area BB and in addition, remains on the array substrate fabricated from the panel region 22. If the transistor group 15 is located in the spacing area 23 between adjacent panel regions 22, after testing of first transistors Q1 through the second transistors Q2 is completed, and when the thin film transistor panel is cut into separate panel regions 22 (each panel region 22 may be used as an array substrate) along the spacing areas 23, the transistor group 15 may be separated from the panel region 22. At this time, the transistor groups 15 and the array substrates made from the panel region 22 are separated by cutting.

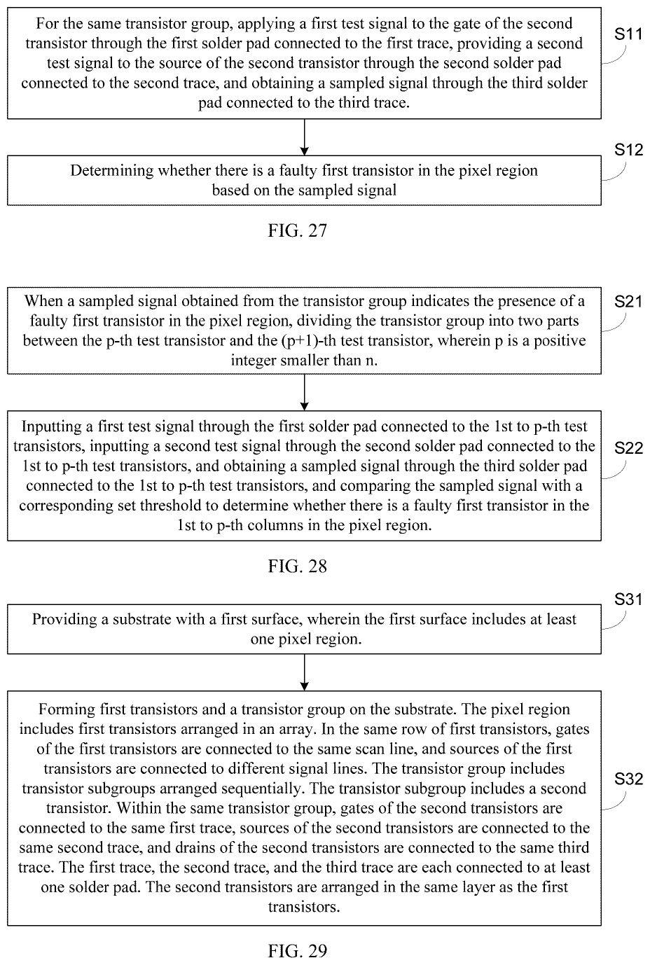

Based on the thin film transistor panels provided in the above embodiments, a testing method for the above thin film transistor panels is provided. The testing method may be shown in FIG. 27.

FIG. 27 is a schematic flow chart of a test method provided by embodiments of the present disclosure. The test method includes:
At S11, for the same transistor group 15, applying a first test signal to the gate G of the second transistor Q2 through the first solder pad 141 connected to the first trace 161, providing a second test signal to the source S of the second transistor Q2 through the second solder pad 142 connected to the second trace 162, and obtaining a sampled signal through the third solder pad 143 connected to the third trace 163, wherein the sampled signal may be a current signal output by the transistor group 15 through the third solder pad 143; and
At S12, determining whether there is a faulty first transistor Q1 in the pixel region based on the sampled signal.

As described above, since the second transistor Q2 and the first transistor Q1 are arranged in the same layer and have the same structure, the performance of the first transistor Q1 may be ensured through the second transistor Q2. Therefore, the sampled signal obtained from the second transistor Q2 may be used to characterize the performance of the first transistor Q1, enabling the detection of whether there is a faulty first transistor Q1 in the pixel region 12.

Optionally, determining whether there is a faulty first transistor Q1 in the pixel region based on the sampled signal includes if the sampled signal exceeds a set threshold, determining the pixel region has a faulty first transistor Q1.

For a panel region 22 with defined design parameters, the size and layout of the first transistors Q1 in the pixel region 12 are fixed. If there is no faulty first transistor Q1, the sampled signal from the second transistors Q2 in a corresponding transistor group 15 has a fixed value. This fixed value may be pre-calibrated using a standard panel and used as a set threshold. When a faulty first transistor Q1 is present, it causes the sampled signal to increase. Therefore, by comparing a sampled signal with a set threshold, the presence of a faulty first transistor Q1 may be determined.

In descriptions below, during a process of determining whether there is a faulty first transistor Q1 using the binary test method, set thresholds required for comparison when a transistor group 15 is divided into different numbers of transistor subgroups 151 may all be pre-calibrated using corresponding reference panels.

Optionally, for the same transistor group 15, when a sampled signal exceeds a set threshold, the testing method further includes along the arrangement direction of the transistor subgroups 151 in the transistor group 15, dividing and testing the transistor group 15 multiple times using the binary test method to determine the location of a faulty first transistor Q1 in the pixel region 12.

As described above, the pixel region 12 may exemplarily have first transistors Q1 arranged in m rows and n columns. Exemplarily, the transistor subgroup 151 in the transistor group 15 is a second transistor Q2, and the arrangement direction of the transistor subgroups 151 is parallel to the row direction X. The transistor group 15 has n second transistors Q2 arranged sequentially along the row direction X. Each second transistor Q2 is arranged opposite to a column of first transistors Q1 along the column direction Y. Along the row direction X, the n second transistors Q2 are sequentially the 1st test transistor to the nth test transistor. Based on this, the method for determining whether there is a faulty first transistor Q1 using the binary test method is as shown in FIG. 28.

For the same transistor group 15, since multiple second transistors Q2 are connected in parallel through the first trace 161, the second trace 162, and the third trace 163, the second transistors Q2 in the same transistor group 15 may perform tests simultaneously. This allows for testing as a whole to determine whether there is a faulty first transistor Q1 in the pixel region 12. When a faulty first transistor Q1 is detected, the binary test method may be applied to narrow down and determine the location of the faulty first transistor Q1 in the pixel region 12. Therefore, compared to schemes where transistors are tested separately at separate positions, the number of tests is reduced and testing efficiency is improved.

Furthermore, in some embodiments, the arrangement of the second transistors Q2 in the transistor group 15 may be the same as that of the first transistors Q1 in the pixel region. Specifically, the size of the second transistors Q2 may be set to be the same as that of the first transistors Q1. Along the length direction of a parallel and opposite side edge, the spacing between the second transistors Q2 may be the same as that between the first transistors Q1. As such, the second transistors Q2 in a transistor group 15 correspond with a row or column of first transistors Q1 in a one-to-one manner. The second transistors Q2 in the transistor group 15 may more accurately characterize the performance of the first transistors Q1 in the pixel region 12, allowing for more precise testing of whether there is a faulty first transistor Q1 in the pixel region 12. When a faulty first transistor Q1 is detected, its location in the pixel region 12 may be accurately determined.

FIG. 28 is a flow chart of a method for determining a faulty first transistor based on the binary test method provided by embodiments of the present disclosure. The method includes:
At S21, when a sampled signal obtained from the transistor group 15 indicates the presence of a faulty first transistor Q1 in the pixel region 12, dividing the transistor group 15 into two parts between the p-th test transistor and the (p+1)-th test transistor, wherein p is a positive integer smaller than n; and
At S22, inputting a first test signal through the first solder pad 141 connected to the 1st to p-th test transistors, inputting a second test signal through the second solder pad 142 connected to the 1st to p-th test transistors, and obtaining a sampled signal through the third solder pad 143 connected to the 1st to p-th test transistors, and comparing the sampled signal with a corresponding set threshold to determine whether there is a faulty first transistor Q1 in the 1st to p-th columns in the pixel region 12.

With the same method, whether there is a faulty first transistor Q1 in the (p+1)-th to n-th columns may be detected through the (p+1)-th to n-th test transistors.

If there is a faulty first transistor Q1 in the 1st to p-th columns, the 1st to p-th test transistors are divided into two parts using the same method. Based on the two parts, corresponding columns in the pixel region 12 are tested to determine whether there is a faulty first transistor Q1.

If there is a faulty first transistor Q1 in the (p+1)-th to n-th columns, the (p+1)-th to n-th test transistors are divided into two parts using the same method. Based on the two parts, corresponding columns in the pixel region 12 are tested to determine whether there is a faulty first transistor Q1.

The transistor group 15 may be divided repeatedly using the above described dividing manner until it is determined whether each column in the pixel region 12 has a faulty first transistor Q1. Therefore, for a transistor group 15 where the arrangement direction of the transistor subgroups 151 is the row direction X, whether each column in the pixel region 12 has a faulty first transistor Q1 may be determined. Similarly, for a transistor group 15 where the arrangement direction of the transistor subgroups 151 is the column direction Y, whether each row in the pixel region 12 has a faulty first transistor Q1 may be determined. By using two transistor groups 15 with perpendicular arrangement directions of the transistor subgroups 151 and employing a row-column intersection locating method, the location of a faulty first transistor Q1 in the pixel region 12 may be determined.

As described above, both the first transistor Q1 and the second transistor Q2 may be IGZO transistors. IGZO transistors in the pixel region 12 are prone to faults caused by conductorization or other characteristic abnormalities. Based on the above illustrated embodiments, whether IGZO transistors in the pixel region 12 have faults may be detected using the transistor group 15.

Taking the detection of conductorization in IGZO transistors in the pixel region 12 as an example. The off-state current of a single device in the transistor group 15 is on the order of 10×10⁻¹⁴ A, while during conductorization, this current is on the order of 10×10⁻⁶ A. If the transistor group 15 contains N second transistors Q2, and the channel width-to-length ratio of the second transistor Q2 is M, the off-state current of the transistor group 15 is I, then the off-state current of a single device is equal to I/(N*M).

Take a substrate 11 with an area of 2600 mm×2250 mm as an example. When the distance between two display pixels in the pixel region 12 ranges from 0.1 mm to 0.2 mm, 3 rows and 4 columns of panel regions 22 may be fabricated. Along the long side of the substrate 11, there may be a maximum of 2600 mm÷(0.1 mm to 0.2 mm)×3=39,000 to 78,000 transistors connected in parallel. If there is no conductorization issue, the off-state current of a single device after parallel connection is on the order of 10×10⁻¹⁰ A, which is significantly different from a conductorization current level of 10×10⁻⁶ A. If a few devices exhibit conductorization, it may be detected that the off-state current is abnormally high. Therefore, in some embodiments, the sampled signal from the transistor group 15 may be an off-state current of the device. By comparing the sampled off-state current with a calibrated set threshold, whether there is a conductorized IGZO transistor in the pixel region 12 may be determined.

In some embodiments, after a source-drain current (I_{DS}) of IGZO transistors is sampled using the transistor group 15, the source-drain current may be combined with a gate-source voltage (V_{GS}) applied to the IGZO transistors during testing, and an I-V curve may be plotted. If conductorization issues exist, the I_{DS} may be abnormally high. Since the transistor group 15 includes second transistors Q2 arranged sequentially, if the range of IGZO transistors detected in a single test is large, the efficiency of detecting conductorization of IGZO transistors may be improved.

As described above, in some embodiments, since the transistor group 15 includes second transistors Q2 arranged sequentially along the first arrangement direction F1, it is possible to measure and determine in one test whether corresponding first transistors Q1 in the pixel region 12 have conductorization issues. If conductorization issues are detected, the transistor group 15 is divided using the binary test method and measured again until the row and column of a conductorized first transistor Q1 are identified. Thus, a conductorized first transistor Q1 in a large-sized substrate 11 may be located quickly and accurately. It improves the efficiency of conductorization detection and enables quick identification of a conductorized location.

Based on the thin film transistor panel and testing method provided in the above embodiments, another embodiment of the present disclosure provides a method for fabricating thin film transistors, as illustrated in FIG. 29.

FIG. 29 is a flow chart illustrating a method for fabricating a thin film transistor panel provided by embodiments of the present disclosure. The method includes:
At S31, providing a substrate 11 with a first surface 111, wherein the first surface 111 includes at least one pixel region 12; and
At S32, forming first transistors Q1 and a transistor group 15 on the substrate 11. The pixel region 12 includes the first transistors Q1 arranged in an array. In the same row of the first transistors Q1, gates of the first transistors Q1 are connected to the same scan line, and sources of the first transistors Q1 are connected to different signal lines. The transistor group 15 includes transistor subgroups 151 arranged sequentially. The transistor subgroup 151 includes a second transistor Q2. In the same transistor group 15, gates of the second transistors Q2 are connected to the same first trace 161, sources of the second transistors Q2 are connected to the same second trace 162, and drains of the second transistors Q2 are connected to the same third trace 163. The first trace 161, the second trace 162, and the third trace 163 are each connected to at least one solder pad 14. The second transistors Q2 are arranged in the same layer as the first transistors Q1.

Here, at least one side edge of the pixel region 12 is parallel and opposite to the transistor group 15. The arrangement direction of the transistor subgroups 151 in the transistor group 15 is parallel to the length direction of the parallel and opposite side edge.

The fabrication method provided in this application may produce the aforementioned thin film transistor panel, enable performance testing of the first transistors Q1 through the second transistors Q2 in the thin film transistor panel, and determine whether there is a faulty first transistor Q1 in the pixel region 12.

Taking a thin film transistor panel as an example. The thin film transistor panel exemplarily has transistors with a channel width-to-length ratio of 4:5.5 and solder pad dimension of 20 μm×10 μm. A transistor group 15 occupies a width of 50 μm. The transistor group 15 may be placed outside the panel region 22, such as in a spacing area 23 that is between panel regions 22 and used for cutting, in a hollowed-out region in a wider trace in a border area BB, or in a part of the border area BB where dummy pixels are arranged. Since the width of the transistor group 15 is relatively small (around 50 μm), its different layout configurations have a relatively small impact on the border area BB.

Optionally, during a fabrication process, the first trace 161, the second trace 162, and the third trace 163 are connected to an electrostatic discharge (ESD) circuit. Connecting the first trace 161, the second trace 162, and the third trace 163 to the ESD circuit during the fabrication of the thin film transistor panel helps prevent electrostatic damage to the traces and transistors in the transistor group 15 during the panel manufacturing process.

In some embodiments, the ESD circuit includes transistors. The transistors in the ESD circuit, the first transistors Q1, and the second transistors Q2 may be arranged in the same layer and fabricated simultaneously using the same process flow. After completing a fabrication process of transistors in a panel, signal lines and electrode structures, such as touch lines and ITO electrode layers, are sequentially formed above the transistors. Adjacent conductive layers are isolated by insulating layers.

Optionally, the fabrication method further includes disconnecting the first trace 161, the second trace 162, and the third trace 163 from the ESD circuit; and testing the first transistors Q1 using the transistor group 15. After disconnecting the ESD circuit from the traces in the transistor group 15, the performance of the first transistors Q1 may be tested using the second transistors Q2 in the transistor group 15 based on the testing methods provided in the above embodiments, which determines whether there is a faulty first transistor Q1 in the pixel region 12.

As described in the embodiments related to the thin film transistor panel, the transistor group 15 may be arranged in the border area BB of the panel region 22 or outside the panel region 22.

If the transistor group 15 is arranged outside the panel region 22, the fabrication method further includes after testing the first transistors Q1 using the transistor group 15, cutting and removing the transistor group 15. In this approach, after completing the testing of the first transistors Q1 using the transistor group 15, the transistor group 15 may be cut and removed. As such, the transistor group 15 does not occupy the layout space in the panel region 22 after the cutting process is completed. Since the array substrate is formed from the panel region 22 and does not include the transistor group 15, the impact of the transistor group 15 on the reliability of the display panel may be minimized.

In the description of the present disclosure, various embodiments are presented in a progressive, parallel, or combined manner, with each embodiment focusing on its differences from other embodiments. The similar or identical parts between different embodiments may be referenced interchangeably. Embodiments provided in this application may be combined when there is no contradiction or conflict.

Notably, in descriptions of the present disclosure, the accompanying drawings and the descriptions of the embodiments are illustrative rather than restrictive. The same reference numerals throughout the specification identify the same structures. Additionally, for clarity and ease of description, the thicknesses of some layers, films, panels, regions, etc. may be exaggerated in the drawings. It should also be understood that when an element such as a layer, film, region, or substrate is described as being “on” another element, it may be directly on the other element or intervening elements may be present. Furthermore, “on” refers to positioning an element above or below another element, but it does not necessarily mean positioning on the upper side of the other element in the direction of gravity.

Terms such as “upper,” “lower,” “top,” “bottom,” “inner,” “outer,” etc., indicate orientations or positional relationships based on the orientations or positional relationships shown in the drawings. These terms are used solely for the convenience of describing this application and simplifying the description, and do not imply or require that the referenced device or component must have a specific orientation or be constructed and operated in a specific orientation. Therefore, these terms should not be construed as limiting the application. When a component is described as being “connected” to another component, it may be directly connected to the other component or intervening components may be present.

It should also be noted that, in this document, relational terms such as “first” and “second” are used solely to distinguish one entity or operation from another, without necessarily implying any actual relationship or order between these entities or operations. Additionally, the terms “include,” “comprise,” or any variations thereof are intended to cover non-exclusive inclusion, so that an item or device including a series of elements not only includes those elements but also may include other elements not explicitly listed or inherent to the item or device. Without further limitations, elements defined by the phrase “including one . . . ” do not exclude the presence of additional identical elements in the item or device that includes the aforementioned elements.

The above description of the disclosed embodiments enables those skilled in the art to implement or use this application. Various modifications to these embodiments will be apparent to those skilled in the art, and the general principles defined herein may be applied to other embodiments without departing from the spirit or scope of this application. Therefore, this application is not limited to the embodiments shown herein but is intended to cover the broadest scope consistent with the principles and novel features disclosed in this document.

What is claimed is:

1. A thin film transistor panel, comprising:
a substrate having a first surface, wherein the first surface includes at least one pixel region, the at least one pixel region includes a plurality of first transistors arranged in an array, and in a same row of the plurality of first transistors, a plurality of gates of the plurality of first transistors are connected to a same scan line, and a plurality of sources of the plurality of first transistors are connected to different signal lines; and
at least one transistor group arranged on the first surface, wherein the at least one transistor group includes a plurality of transistor subgroups arranged in sequence, the plurality of transistor subgroups include a plurality of second transistors, and in a same transistor group, a plurality of gates of the plurality of second transistors are connected to a same first trace, a plurality of sources of the plurality of second transistors are connected to a same second trace, and a plurality of drains of the plurality of the second transistors are connected to a same third trace, the first trace, second trace, and third trace are each connected to at least one solder pad, the plurality of second transistors and the plurality of first transistors are arranged in a same layer, at least one side edge of the at least one pixel region is parallel and opposite to one of the at least one transistor group, and an arrangement direction of the plurality of transistor subgroups in the at least one transistor group is parallel to a length direction of the at least one side edge that is parallel and opposite to the one of the at least one transistor group.

2. The thin film transistor panel according to claim 1, wherein the at least one pixel region includes a first side edge and a second side edge, the first side edge is parallel to a row direction of the array, the second side edge is parallel to a column direction of the array, and the first side edge and the second side edge are respectively provided with one of the at least one transistor group that is parallel and opposite.

3. The thin film transistor panel according to claim 2, wherein the at least one pixel region further includes a third side edge opposite to the first side edge, and a fourth side edge opposite to the second side edge, and at least one of the third side edge and the fourth side edge is provided with one of the at least transistor group that is parallel and opposite.

4. The thin film transistor panel according to claim 1, wherein the at least one pixel region has the plurality of first transistor in m rows and n columns, m and n are both positive integers greater than 1; if one of the at least one transistor groups is parallel and opposite to a side edge of the at least one pixel region that extends along a row direction of the array, the one of the at least one transistor groups has n transistor subgroups, each of the n transistor subgroup corresponds to a column of the plurality of first transistors; and if one of the at least one transistor groups is parallel and opposite to a side edge of the at least one pixel region that extends along a column direction of the array, the one of the at least one transistor groups has m transistor subgroups, each of the m transistor subgroup corresponds to a row of the first transistors.

5. The thin film transistor panel according to claim 1, wherein for a same transistor group, adjacent transistor subgroups are connected in parallel using a control switch.

6. The thin film transistor panel according to claim 1, wherein the plurality of transistor subgroup include the plurality of second transistors arranged in sequence; and for a same transistor group, an arrangement direction of the plurality of second transistors in the plurality of transistor subgroups is perpendicular to the arrangement direction of the transistor subgroup in the at least one transistor group.

7. The thin film transistor panel according to claim 1, wherein the first surface further includes at least one panel region, the at least one panel region includes one of the at least one pixel region and a border area surrounding the one of the at least one pixel area; and for a same panel region, the one of the at least one transistor group that is parallel and opposite to at least one side edge of the at least one pixel region is arranged in the border area.

8. The thin film transistor panel according to claim 7, wherein the border area includes a first region surrounding the at least one pixel region and a second region surrounding the first region, the first region is used to set a dummy pixel and a dummy pixel circuit corresponding to the dummy pixel, the at least one pixel region is provided with a display pixel and a pixel circuit connected to the display pixel, the pixel circuit includes one of the plurality of first transistors, the at least one transistor group is located in the first region, a thin film transistor in the dummy pixel circuit serves as the second transistor, and the dummy pixel is disconnected from the dummy pixel circuit.

9. The thin film transistor panel according to claim 8, wherein the border area on one side of the at least one pixel area has a shift register circuit, the border area on another side of the at least one pixel area has the at least one transistor group, and the one side and the other side are opposite.

10. The thin film transistor panel according to claim 7, wherein the border area includes a first region surrounding the at least one pixel region and a second region surrounding the first region, the first region is used to set a dummy pixel and a dummy pixel circuit corresponding to the dummy pixel, and the at least one transistor group is located in the second region.

11. The thin film transistor panel according to claim 7, wherein the first surface further includes a plurality of panel regions arranged in an array, there is a spacing areas between adjacent panel areas of the plurality of panel regions, the at least one transistor group is provided in the border area of the at least one panel region.

12. The thin film transistor panel according to claim 7, wherein the border area has a fourth trace surrounding the at least one pixel area, the fourth trace is used to access a fixed voltage, the fourth trace has a hollowed-out region, and the at least one transistor group is located in the hollowed-out area.

13. The thin film transistor panel according to claim 1, wherein the first surface further includes at least one panel region, the at least one panel region includes one of the at least one pixel region and a border area surrounding the one of the at least one pixel region, and the at least one transistor group is outside the border area.

14. The thin film transistor panel according to claim 13, wherein when there are a plurality of panel regions, a spacing area is arranged between adjacent panel regions of the plurality of panel regions, the at least one transistor group is located in the spacing area, and the adjacent panel areas share a same transistor group of the at least one transistor group.

15. A testing method for a thin film transistor panel, wherein the thin film transistor panel comprises:
a substrate having a first surface, wherein the first surface includes at least one pixel region, the at least one pixel region includes a plurality of first transistors arranged in an array, and in a same row of the plurality of first transistors, a plurality of gates of the plurality of first transistors are connected to a same scan line, and a plurality of sources of the plurality of first transistors are connected to different signal lines; and
at least one transistor group arranged on the first surface, wherein the at least one transistor group includes a plurality of transistor subgroups arranged in sequence, the plurality of transistor subgroups include a plurality of second transistors, and in a same transistor group, a plurality of gates of the plurality of second transistors are connected to a same first trace, a plurality of sources of the plurality of second transistors are connected to a same second trace, and a plurality of drains of the plurality of the second transistors are connected to a same third trace, the first trace, second trace, and third trace are each connected to at least one solder pad, the plurality of second transistors and the plurality of first transistors are arranged in a same layer, at least one side edge of the at least one pixel region is parallel and opposite to one of the at least one transistor group, and an arrangement direction of the plurality of transistor subgroups in the at least one transistor group is parallel to a length direction of the at least one side edge that is parallel and opposite to the one of the at least one transistor group, the method comprises:
for a same transistor group of the at least one transistor group, applying a first test signal to a gate of the plurality of second transistors through a first solder pad connected to the first trace, providing a second test signal to a source of the plurality of second transistors through a second solder pad connected to the second trace, and obtaining a sampled signal through a third solder pad connected to the third trace; and
determining whether there is a faulty first transistor in the at least one pixel region based on the sampled signal.

16. The method according to claim 15, wherein determining whether there is a faulty first transistor in the at least one pixel region based on the sampled signal includes:
if the sampled signal is greater than a set threshold, determining the at least one pixel region has a faulty first transistor.

17. The method according to claim 16, wherein for a same transistor group, when the sampled signal is greater than the set threshold, the method further includes:
along the arrangement direction of the plurality of transistor subgroups, dividing the at least one transistor group multiple times using a binary test method to determine a location of the faulty first transistor in the at least one pixel region.

18. A method for fabricating a thin film transistor panel, comprising:
providing a substrate with a first surface, wherein the first surface includes at least one pixel region; and
forming a plurality of first transistors and a transistor group on the substrate, the at least one pixel region includes the plurality of first transistors arranged in an array; in a same row of the plurality of first transistors, a plurality of gates of the plurality of first transistors are connected to a same scan line, a plurality of sources of the plurality of first transistors are connected to different signal lines; the transistor group includes a plurality of transistor subgroups arranged sequentially, one of the plurality of transistor subgroups includes a second transistor; in a same transistor group, a plurality of gates of the second transistors are connected to a same first trace, a plurality of sources of the second transistors are connected to a same second trace, and a plurality of drains of the second transistors are connected to a same third trace; the first trace, the second trace, the third trace are each connected to at least one solder pad; the second transistor is arranged in a same layer as the plurality of first transistors; at least one side edge of the at least one pixel region is parallel and opposite to the transistor group, and an arrangement direction of the plurality of transistor subgroups in the transistor group is parallel to a length direction of the at least one side edge of the at least one pixel region that is parallel and opposite to the transistor group.

19. The method according to claim 18, further comprising:
during a preparation process, connecting the first trace, the second trace, and the third trace to an electrostatic discharge circuit;
disconnecting the first trace, the second trace, and the third trace from the electrostatic discharge circuit; and
based on the transistor group, testing the plurality of first transistors.

20. The method according to claim 18, further comprising:
after testing the plurality of first transistors through the transistor group, cutting and removing the transistor group.
